(19) United States
(12) Patent Application Publication
(10) Pub. No.: US 2026/0121635 A1
(43) Pub. Date: Apr. 30, 2026

(54) DRIVER HAVING MULTIPLE OPERATING MODES

(71) Applicant: SigmaStar Technology Ltd., Xiamen (CN)

(72) Inventors: Xiang ZHANG, Shanghai (CN); Zhenyang PANG, Shanghai (CN); Zewei HE, Shanghai (CN)

(21) Appl. No.: 19/342,829

(22) Filed: Sep. 29, 2025

(30) Foreign Application Priority Data
Oct. 25, 2024 (CN) 202411505707.8

(51) Int. Cl. H03K 17/687

(52) U.S. Cl. CPC H03K 17/6871

(57) ABSTRACT

A driver includes a current-mode driving circuit and a voltage-mode driving circuit. The current-mode driving circuit is activated in a current mode or a hybrid mode to generate a first signal to an output pad according to a first data signal. The voltage-mode driving circuit is activated in a voltage mode or the hybrid mode to generate a second signal to the output pad according to the first data signal, and provides a matching resistor to the output pad in the current mode, the voltage mode or the hybrid mode. The output pad outputs the first signal, the second signal and a combination of the first and second signals in the current mode, the voltage mode and the hybrid mode, respectively, wherein a swing of the first signal is lower than a swing of the second signal.

This application claims the benefit of China application Serial No. CN202411505707.8, filed on Oct. 25, 2024, the subject matter of which is incorporated herein by reference.

### BACKGROUND OF THE INVENTION

### Field of the Invention

The present application relates to a driver, and more particularly to a driver having multiple operating modes, wherein the driver is able to provide different output swings in these operating modes.

### Description of the Related Art

A driver is often used in data transmission applications, and may be applied to enhance driving abilities of data signals to allow a receiving device to receive intact signals for subsequent signal processing. If an existing low power-consuming driver is used to provide a higher output swing, such existing driver is nonetheless restricted by a power supply voltage and may fail to provide a required output swing. On the other hand, if a differently structured driver is used to support a higher output swing, the overall power consumption of the driver may be significantly increased. As such, it is difficult for existing drivers to meet different applications of scenarios of high output swings and low power consumption.

### SUMMARY OF THE INVENTION

In some embodiments, it is an object of the present application to provide a driver having multiple operating modes, wherein the driver is able to provide different output swings in these operating modes so as to improve the issues of the prior art.

In some embodiments, a driver includes a current-mode driving circuit and a voltage-mode driving circuit. The current-mode driving circuit is activated in a current mode or a hybrid mode to generate a first signal to an output pad according to a first data signal. The voltage-mode driving circuit is activated in a voltage mode or the hybrid mode to generate a second signal to the output pad according to the first data signal, and provides a matching resistor to the output pad in the current mode, the voltage mode or the hybrid mode. The output pad outputs the first signal in the current mode, outputs the second signal in the voltage mode, and outputs a combination of the first signal and the second signal in the hybrid mode, wherein a swing of the first signal is lower than a swing of the second signal.

Features, implementations and effects of the present application are described in detail in preferred embodiments with the accompanying drawings below.

### BRIEF DESCRIPTION OF THE DRAWINGS

To better describe the technical solution of the embodiments of the present application, drawings involved in the description of the embodiments are introduced below. It is apparent that, the drawings in the description below represent merely some embodiments of the present application, and other drawings apart from these drawings may also be obtained by a person skilled in the art without involving inventive skills.

FIG. 1 shows a schematic diagram of a driver according to some embodiments of the present application.

FIG. 2A shows an equivalent schematic diagram of the voltage-mode driving circuit in FIG. 1 according to some embodiments of the present application.

FIG. 2B shows a schematic diagram of the inverter circuit in FIG. 2A according to some embodiments of the present application.

FIG. 3 shows a schematic diagram of the current-mode driving circuit in FIG. 1 according to some embodiments of the present application.

FIG. 4 shows a schematic diagram of a driver according to some embodiments of the present application.

### DETAILED DESCRIPTION OF THE INVENTION

All terms used in the literature have commonly recognized meanings. Definitions of the terms in commonly used dictionaries and examples discussed in the disclosure of the present application are merely exemplary, and are not to be construed as limitations to the scope or the meanings of the present application. Similarly, the present application is not limited to the embodiments enumerated in the description of the application.

The term “coupled” or “connected” used in the literature refers to two or multiple elements being directly and physically or electrically in contact with each other, or indirectly and physically or electrically in contact with each other, and may also refer to two or more elements operating or acting with each other. As given in the literature, the term “circuit” may be a device connected by at least one transistor and/or at least one active element by a predetermined means so as to process signals.

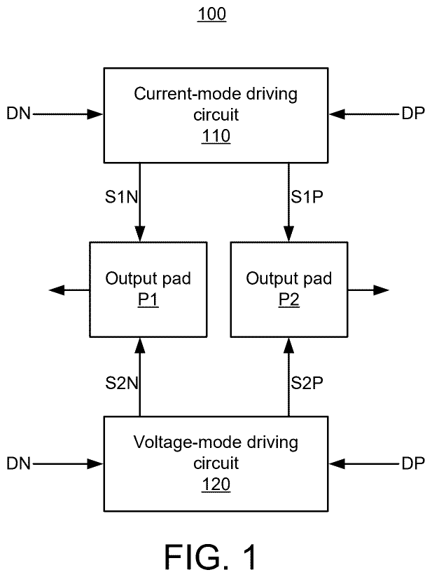

FIG. 1 shows a schematic diagram of a driver 100 according to some embodiments of the present application. The driver 100 is a data driver having multiple operating modes, and is able to provide corresponding circuit configurations according to operating requirements of different applications (including, for example but not limited to, signal swings and power consumption). In some embodiments, the multiple operating modes above include a voltage mode, a current mode and a hybrid mode (equivalent to simultaneously activating the voltage mode and the current mode).

The driver 100 includes a current-mode driving circuit 110 and a voltage-mode driving circuit 120. The current-mode driving circuit 110 and the voltage-mode driving circuit 120 are coupled in parallel to an output pad P1 and an output pad P2. The current-mode driving circuit 110 is activated in the current mode or the hybrid mode to generate a signal S1N to the output pad P1 according to a data signal DN and generate a signal S1P to the output pad P2 according to a data signal DP. In some embodiments, the data signal DN and the data signal DP are differential signals. That is, when the data signal DP is at a low level (for example, corresponding to logical 0), the data signal DN is at a high level (for example, corresponding to logical 1); and vice versa. Similarly, the signal S1N and the signal S1P may also be differential signals.

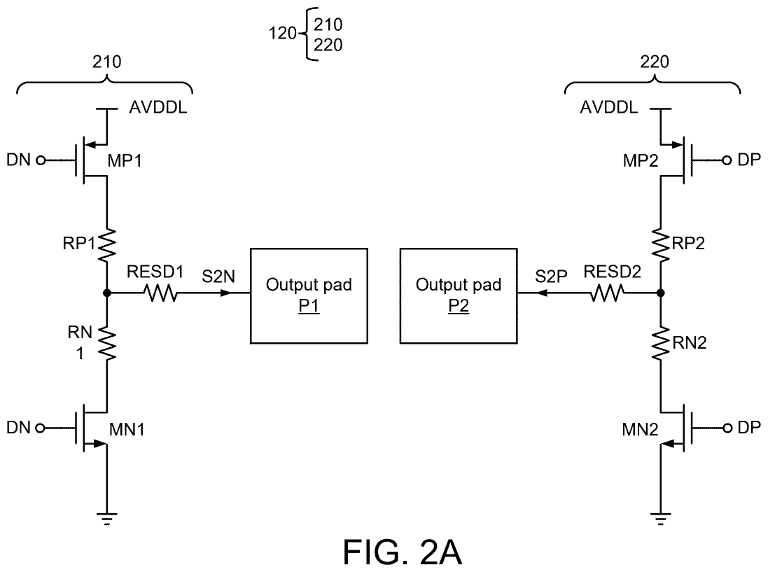

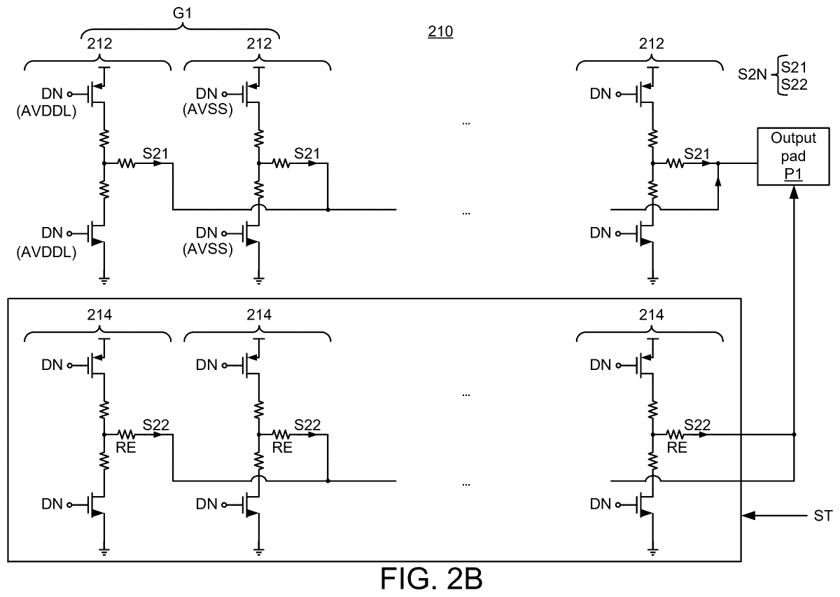

The voltage-mode driving circuit 120 is activated in the voltage mode or the hybrid mode to generate a signal S2N to the output pad P1 according to the data signal DN and generate a signal S2P to the output pad P2 according to the data signal DP. Similarly, the signal S2N and the signal S2P may also be differential signals. On the other hand, in the current mode, the voltage mode or the hybrid mode, the voltage-mode driving circuit 120 further provides a matching resistor (for example, the resistor RESD1 and/or the resistor RESD2 in FIG. 2A) to the output pad P1 and the output pad P2. Because the output pad P1 and the output pad P2 are configured to couple to a receiving device (not shown) to transmit the signal S1P, the signal S1N, the signal S2N and the signal S2P to the receiving device, each of the output pad P1 and the output pad P2 in any mode is able to provide an appropriate matching resistor by the voltage-mode driving circuit 120, so as to prevent over-attenuation caused by load effects during transmissions of the signals above.

In some embodiments, the driver 100 further includes a register (not shown), which is able to generate corresponding circuit configuration parameters according to a mode control signal, so that the current-mode driving circuit 110 and the voltage-mode driving circuit 120 operate in a corresponding one of the voltage mode, the current mode and the hybrid mode according to these circuit configuration parameters. In some embodiments, the driver 100 may include a detection circuit, which may adjust the mode control signal according to a signal swing needed for the current application to switch the operating modes above. Alternatively, in some other embodiments, a user may input the mode control signal via an external circuit or software to switch the operating modes above.

In different operating modes, the signal swings output from the output pad P1 and the output pad P2 have different level ranges. For example, the output pad P1 outputs the signal S1N, the signal S2N and a combination of the signal S1N and the signal S2N in the current mode, the voltage mode and the hybrid mode, respectively, wherein the swing of the signal S1N is lower than the swing of the signal S2N, and the swing of the signal S2N is lower than the swing of the combination (equivalent to a sum of the signal S1N and the signal S2N) of the signal S1N and the signal S2N. Similarly, the output pad P2 outputs the signal S1P, the signal S2P and a combination of the signal S1P and the signal S2P in the current mode, the voltage mode and the hybrid mode, respectively, wherein the swing of the signal S1P is lower than the swing of the signal S2P, and the swing of the signal S2P is lower than the swing of the combination (equivalent to a sum of the signal S1P and the S2P) of the signal S1P and the signal S2P.

FIG. 2A shows an equivalent schematic diagram of the voltage-mode driving circuit 120 in FIG. 1 according to some embodiments of the present application. In some embodiments, the voltage-mode driving circuit 120 is operable as the inverter circuit 210 and the inverter circuit 220 shown in FIG. 2A.

The inverter circuit 210 includes a transistor MP1, a resistor RP1, a resistor RN1, a resistor RESD1 and a transistor MN1. A first terminal (for example, the source) of the transistor MP1 receives a power supply voltage AVDDL, a second terminal (for example, the drain) of the transistor MP1 is coupled to a first terminal of the resistor RP1, and a control terminal (for example, the gate) of the transistor MP1 receives the data signal DN. A second terminal of the resistor RP1 is coupled to a first terminal of the resistor RN1 and a first terminal of the resistor RESD1, a second terminal of the resistor RESD1 is coupled to the output pad P1 and outputs the signal S2N, and a second terminal of the resistor RN1 is coupled to a first terminal (for example, the drain) of the transistor MN1. A second terminal (for example, the source) of the transistor MN1 is coupled to ground, and a control terminal (for example, the gate) of the transistor MN1 receives the data signal DN.

In the voltage mode or the hybrid mode, when the data signal DN is logical 1, the transistor MP1 is turned off and the transistor MN1 is turned on to generate the signal S2N in logical 0; alternatively, when the data signal DN is logical 0, the transistor MP1 is turned on and the transistor MN1 is turned off to generate the signal S2N in logical 1. On the other hand, in the current mode, the data signal DN received by the transistor MP1 is switched to a signal in logical 0, hence turning off the transistor MP1. In this case, the inverter circuit 210 is not activated, and only a signal path including the resistor RESD1, the resistor RN1 and the transistor MN1 is provided to the output pad P1, thereby providing a matching resistor (for example, the resistor RESD1) to the output pad P1. In some embodiments, the resistor RP1 and/or the resistor RN1 may be selectively provided; however, the present application is not limited to the example above. Similarly, the inverter circuit 220 includes a transistor MP2, a resistor RP2, a resistor RN2, a resistor RESD2 and a transistor MN2, and is used to process the data signal DP. The connections and operations of the elements of the inverter circuit 220 are substantially the same as those of the inverter circuit 210, and such repeated details are omitted herein.

FIG. 2B shows a schematic diagram of the inverter circuit 210 in FIG. 2A according to some embodiments of the present application. In some embodiments, each of the inverter circuit 210 and the inverter circuit 220 in FIG. 2A may be implemented by multiple inverters. Taking the inverter circuit 210 for example, the inverter circuit 210 may include multiple inverters 212 and multiple inverters 214. The multiple inverters 212 are primarily used to adjust the swing of the signal S2N, and the multiple inverters 214 are primarily used to adjust the resistance value of the matching resistor. The multiple inverters 212 and the multiple inverters 214 are coupled in parallel to the output pad P1. The circuit structure of each of the multiple inverters 212 is the same as that of the inverter circuit 210 in FIG. 2A, and the circuit structure of each of the multiple inverters 214 is also the same as that of the inverter circuit 210 in FIG. 2A. When the multiple inverters 212 and the multiple inverters 214 are activated, the activated inverters are equivalently connected in parallel and operate as the inverter circuit 210 in FIG. 2A.

The multiple inverters 212 are coupled in parallel to one another to the output pad P1, and the number of activated inverters among the multiple inverters 212 is able to adjust the swing of the signal S2N. The multiple inverters 212 may be activated in the voltage mode or the hybrid mode to generate multiple sub-signals S21 to the output pad P1 according to the data signal DN. The multiple inverters 214 may be activated in the current mode, the voltage mode or the hybrid mode to generate multiple sub-signals S22 to the output pad P1 according to the data signal DN, wherein the multiple sub-signals S21 and the multiple sub-signals S22 are transmitted to the output pad P1 to generate the signal S2N. That is, a sum of the multiple sub-signals S21 and the multiple sub-signals S22 is the signal S2N.

In some embodiments, the swing of the signal S2N gets lower as the number of activated inverters among the multiple inverters 212 increases. More specifically, as described above, the multiple inverters 212 are primarily used to adjust the swing of the signal S2N. Two inverters among the multiple inverters 212 may form one inverter group. For example, the two leftmost inverters may be configured as an inverter group G1. To lower the swing of the signal S2N, the data signal DN received by one inverter 212 in the inverter group G1 may be switched to the power supply signal AVDDL, and the data signal DN received by the other inverter 212 in the inverter group G1 is switched to a ground voltage (or a low power supply voltage VSS). Thus, both of the inverters 212 in the inverter group G1 are activated and are normally on (that is, one N-type transistor in the inverter group G1 is turned on by the power supply voltage AVDDL and one P-type transistor is turned on by the low power supply voltage VSS, such that the inverter group G1 forms a connected current path), hence lowering the swing of the multiple sub-signals S21 generated by the multiple inverters 212. Similarly, the number of inverter groups that are normally on increases if the number of activated inverters among the multiple inverters 212 increases, such that the swing of the multiple sub-signals S21 gets lower and the swing of the signal S2N is accordingly lowered. Therefore, it is understandable that, the power consumption of the voltage-mode driving circuit 120 gets larger as the number of activated inverters among the multiple inverters 212 increases. Accordingly, it is understandable that, the power consumption of the voltage-mode driving circuit 120 gets larger as the swing of the signal S2N gets smaller.

In some embodiments, the number of activated inverters among the multiple inverters 214 is determined according to a trimming signal ST to adjust the resistance value of the matching resistor. In some embodiments, the voltage-mode driving circuit 120 may further include a switching logic circuit (not shown), which may generate multiple control bits according to the trimming signal ST, wherein the multiple control bits may be used to respectively activate the multiple inverters 214. For example, the driver 100 may determine according to these control bits whether to power a corresponding inverter among these inverters 214. Alternatively, the driver 100 may perform an additional logical operation on the control bits and the data signal DN, and then respectively input operation results obtained to these inverters 214 to selectively activate these inverters 214. Various control mechanisms that activate a corresponding number of inverters among the inverters 214 according to the trimming signal ST are to be encompassed within the scope of the present application. The number of resistors (labeled as resistors RE) coupled in parallel to the output pad P1 increases as the number of activated inverters among the multiple inverters 214 increases, hence reducing the resistance value of the resistor RESD1 (equivalent to the matching resistor described above).

In some embodiments, by performing equivalent circuit analysis on the circuit in FIG. 2B (for example, treating the circuit in FIG. 2A in equivalence), it can be learned that a maximum swing of the signal S2N output by the output pad P1 when the voltage-mode driving circuit 120 is in the voltage mode or the hybrid mode is one-half of the power supply voltage AVDDL. If the swing of the signal S2N is to be lowered, the number of activated inverters among the multiple inverters 212 needs to be increased, hence leading to increased power consumption of the voltage-mode driving circuit 120.

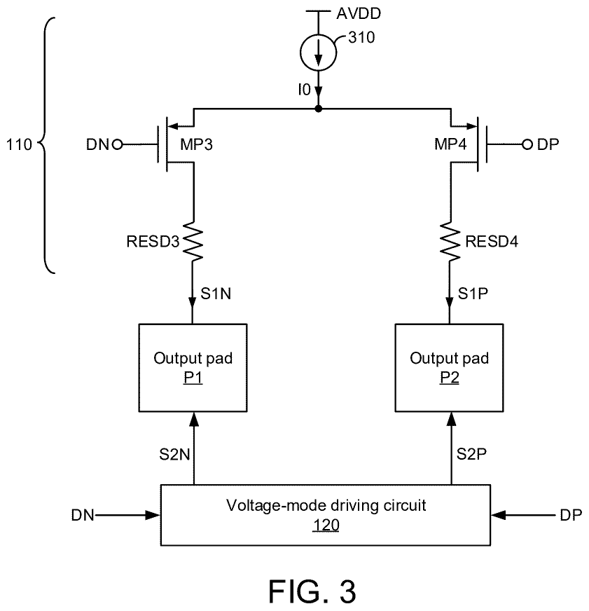

FIG. 3 shows a schematic diagram of the current-mode driving circuit 110 in FIG. 1 according to some embodiments of the present application. The current-mode driving circuit 110 includes a current source 310, a transistor MP3, a resistor RESD3, a transistor MP4 and a resistor RESD4. The current source 310 is powered by a power supply voltage AVDD, and is activated in the current mode or the hybrid mode to generate a current IO. A first terminal of the transistor MP3 is coupled to the current source 310 to receive the current IO, a second terminal of the transistor MP3 is coupled to a first terminal of the resistor RESD3, and a control terminal of the transistor MP3 receives the data signal DN. The transistor MP3 may be turned on according to the data signal DN. A second terminal of the resistor RESD3 is coupled to the output pad P1, and outputs the current IO as the signal S1N when the transistor MP3 is turned on. Connections among the current source 310, the transistor MP4 and the resistor RESD4 are similar to connections among the current source 310, the transistor MP3 and the resistor RESD3, and main differences lie in that, the transistor MP4 is turned on according to the data signal DP and the resistor RESD4 is coupled to the output pad P2, while other similar details are omitted herein for brevity.

As described above, in any one of the voltage mode, the current mode and/or the hybrid mode, the voltage-mode driving circuit 120 provides a matching resistance to the output pad P1 and the output pad P2. Thus, when the data signal DN is logical 0 and the data signal DP is logical 1, the inverter circuit 210 in FIG. 2A provides a signal path from the resistor RESD1 to the power supply voltage AVDDL to the output pad P1; alternatively, if the data signal DN is logical 1 and the data signal DP is logical 0, the inverter circuit 210 in FIG. 2A provides a signal path from the resistor RESD1 to ground to the output pad P1, thereby adjusting the equivalent resistance of the output pad P1 relative to a receiving device. Similarly, related operations of the inverter circuit 220 in FIG. 2A provide a signal path from the resistor RESD2 to the output pad P2 can be understood accordingly. Thus, on the basis of the operations and circuit analysis above, it may be deduced that the signal S1N output through the output pad P1 when the current-mode driving circuit 110 is in the current mode or the hybrid mode is directly proportional to the current IO generated by the current source 310. Alternatively, intuitively speaking, since the output pad P1 outputs the current IO as the signal S1N when the transistor MP3 is turned on, the swing of the signal S1N increases as the current IO gets larger. Thus, the current IO gets larger if the swing of the signal S1N increases, such that the power consumption of the current-mode driving circuit 110 also increases. Similarly, the signal S1P output through the output pad P2 when the current-mode driving circuit 110 is in the current mode or the hybrid mode is also directly proportional to the current IO.

With the same analysis, if the swing of the signal S1N generated in the current mode is set to the maximum swing (that is, one-half of the power supply voltage AVDDL) of the signal S2N generated in the voltage mode, it is learned that the power consumption generated by the current-mode driving circuit 110 is higher than the power consumption generated by the voltage-mode driving circuit 120. Accordingly, it can be deduced that the current-mode driving circuit 110 is more suitable for application scenarios (lower power consumption generated with respect to low swings) of low swings (for example, apparently less than one-half of the power supply voltage AVDDL, and for example but not limited to, ⅓ of the power supply voltage AVDDL), and the voltage-mode driving circuit 120 is more suitable for application scenarios of high swings (higher power consumption generated with respect to low swings).

On the other hand, in the hybrid mode, the output pad P1 sums up the signal S1N and the signal S2N, and outputs the combination of the signal S1N and the signal S2N to a receiving device. Thus, the swings of the signal S1N and the signal S2N are summed up to become larger. Similar relations are also applicable to the signal S1P and the signal S2P output by the output pad P2. Accordingly, with the consideration of the individual power consumption corresponding to each of the voltage mode, the current mode and the hybrid mode, transmission cable applications and swings suitable for outputs in the current mode, the voltage mode and the hybrid mode of the driver 100 may be summarized as the table below:

| | Transmission cable | |
|---|---|---|
| Operating mode | application | Swing |
| Current mode | Short reach | <<AVDDL/2 |
| Voltage mode | Middle reach | ≤AVDDL/2 |
| Hybrid mode | Long reach | >AVDDL/2 |

In some actual applications, on the basis of different transmission protocols, reaches of transmission cables needed may be different. For example, three transmission reaches are defined in the V-by-one transmission protocol: short reach transmission, middle reach transmission and long reach transmission. The driver 100 may provide different corresponding configurations in different operating modes, so as to adapt to the different transmission reach requirements above.

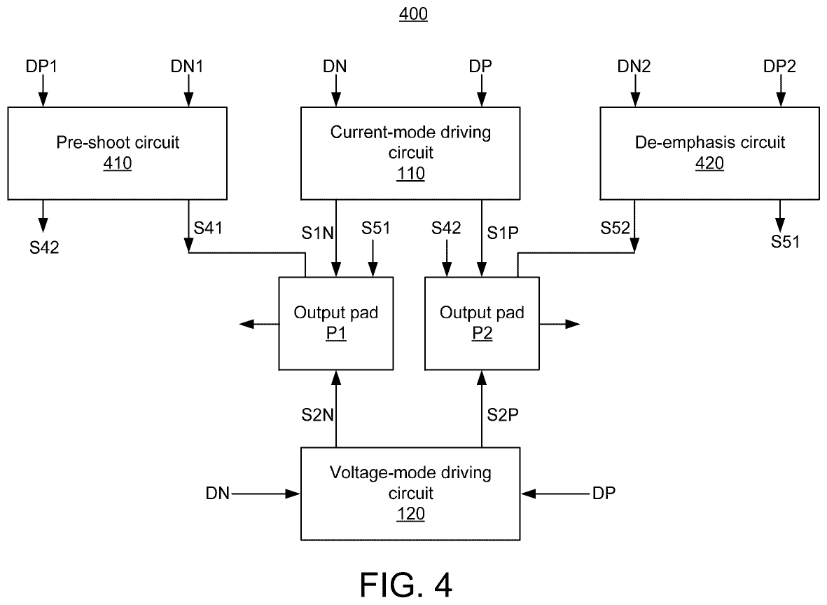

FIG. 4 shows a schematic diagram of a driver 400 according to some embodiments of the present application. Compared to the driver 100, in this example, the driver 400 further includes a pre-shoot circuit 410 and a de-emphasis circuit 420, which are primarily used to perform equalization. The pre-shoot circuit 410 is activated in the hybrid mode to generate a signal S41 to the output pad P1 according to a data signal DN1 and generate a signal S42 to the output pad P2 according to a data signal DP1. The de-emphasis circuit 420 is activated in the hybrid mode to generate a signal S51 to the output pad P1 according to a data signal DN2 and generate a signal S52 to the output pad P2 according to a data signal DP1. In some embodiments, the circuit structure of each of the pre-shoot circuit 410 and the de-emphasis circuit 420 may be the same as the circuit structure of the current-mode driving circuit 110. In some embodiments, the data signal DN1, the data signal DN and the data signal DN2 sequentially differ by a predetermined time difference, and the data signal DP1, the data signal DP and the data signal DP2 also sequentially differ by the predetermined time difference. For example, if the data signal DN1 is represented as DN (t), the data signal DN may be represented as DN (t+1) and the data signal DN2 may be represented as DN (t+2). In other words, the driver 400 may further include a delay circuit (not shown) so as to generate the multiple data signals above according to the data signal DN. Similar relations are also applicable to the data signal DP1, the data signal DP and the data signal DP2.

In conclusion, the driver provided according to some embodiments of the present application has multiple operating modes, and is able to provide different output signals in different operating modes with the consideration of the overall power consumption, so as to adapt to application requirements of multiple transmission reaches.

While the present application has been described by way of example and in terms of the preferred embodiments, it is to be understood that the disclosure is not limited thereto. Various modifications may be made to the technical features of the present application by a person skilled in the art on the basis of the explicit or implicit disclosures of the present application. The scope of the appended claims of the present application therefore should be accorded with the broadest interpretation so as to encompass all such modifications.

What is claimed is:

1. A driver, comprising:
a current-mode driving circuit, activated in a current mode or a hybrid mode to generate a first signal to an output pad according to a first data signal; and
a voltage-mode driving circuit, activated in a voltage mode or the hybrid mode to generate a second signal to the output pad according to the first data signal, and providing a matching resistor to the output pad in the current mode, the voltage mode or the hybrid mode,
wherein, the output pad outputs the first signal in the current mode, outputs the second signal in the voltage mode, and outputs a combination of the first signal and the second signal in the hybrid mode, wherein a swing of the first signal is lower than a swing of the second signal.

2. The driver according to claim 1, wherein the swing of the second signal is lower than a swing of the combination of the first signal and the second signal.

3. The driver according to claim 1, wherein the voltage-mode driving circuit comprises:
a plurality of first inverters, activated in the voltage mode or the hybrid mode to generate a plurality of first sub-signals to the output pad according to the first data signal; and
a plurality of second inverters, activated in the voltage mode, the current mode or the hybrid mode to generate a plurality of second sub-signals to the output pad according to the first data signal so as to provide the matching resistor, wherein a sum of the plurality of first sub-signals and the plurality of second sub-signals is the second signal.

4. The driver according to claim 3, wherein the plurality of first inverters are used to adjust the swing of the second signal.

5. The driver according to claim 3, wherein the swing of the second signal gets lower as a number of activated inverters among the plurality of first inverters increases.

6. The driver according to claim 3, wherein a number of activated inverters among the plurality of second inverters is determined according to a trimming signal to adjust a resistance value of the matching resistor.

7. The driver according to claim 1, wherein power consumption of the voltage-mode driving circuit increases as the swing of the second signal gets smaller.

8. The driver according to claim 1, wherein the current-mode driving circuit comprises:
a current source, activated in the current mode or the hybrid mode to generate a current;
a transistor, turned on according to the first data signal; and
a resistor, coupled between the output pad and the transistor, and outputting the current as the first signal when the transistor is turned on.

9. The driver according to claim 1, wherein power consumption of the current-mode driving circuit increases as the swing of the first signal gets larger.

10. The driver according to claim 1, further comprising:
a pre-shoot circuit, activated in the hybrid mode to generate a fourth signal to the output pad according to a second data signal; and
a de-emphasis circuit, activated in the hybrid mode to generate a fifth signal to the output pad according to a third data signal,
wherein a circuit structure of each of the pre-shoot circuit and the de-emphasis circuit is same as a circuit structure of the current-mode driving circuit, and the second data signal, the first data signal and the third data signal sequentially differ by a predetermined time difference.
